(19) United States
(12) Patent Application Publication
(10) Pub. No.: US 2026/0212803 A1
(43) Pub. Date: Jul. 23, 2026

(54) PIXELS, DISPLAY DEVICE INCLUDING THE SAME, AND DISPLAY SYSTEM INCLUDING THE SAME

(71) Applicant: Samsung Display Co., Ltd., Yongin-si (KR)

(72) Inventors: Jin Wook YANG, Yongin-si (KR); Bon Seog GU, Yongin-si (KR); Jin Young ROH, Yongin-si (KR); Young Ha SOHN, Yongin-si (KR); Jae Hyeon JEON, Yongin-si (KR); Eui Myeong CHO, Yongin-si (KR)

(21) Appl. No.: 19/367,710

(22) Filed: Oct. 23, 2025

(30) Foreign Application Priority Data
Jan. 22, 2025 (KR) 10-2025-0009766

(51) Int. Cl. G09G 3/32; G09G 3/3233; G09G 3/3266; G09G 3/3275

(52) U.S. Cl. CPC G09G 3/32; G09G 3/3233; G09G 3/3266; G09G 3/3275; G09G 2310/0267; G09G 2310/0275; G09G 2310/08

(57) ABSTRACT

A pixel of a display device includes: a first transistor connected between a first node and a second node, and including a gate electrode connected to a third node, the first node being connected to a first power supply voltage node; a second transistor connected between a data line and the third node, and including a gate electrode connected to a first sub-gate line; a third transistor connected between a reference voltage node and the third node, and including a gate electrode connected to a second sub-gate line; a first capacitor connected between the third node and a fourth node; a fourth transistor connected between the second node and the fourth node, and including a gate electrode connected to a first sub-light emitting control line; and a light emitting element connected between the fourth node and a second power supply voltage node.

### CROSS-REFERENCE TO RELATED APPLICATION

The present application claims priority to and the benefit of Korean Patent Application No. 10-2025-0009766, filed on Jan. 22, 2025, the entire disclosure of which is incorporated by reference herein.

### BACKGROUND

### Field

Aspects of embodiments of the present disclosure relate to an electronic device, and more specifically, to pixels, a display device including the pixels, and a display system including the pixels.

### Discussion of the Background

With the development of information technology, the importance of a display device, which is a connection medium between a user and information, is being highlighted. Accordingly, the usage of display devices, such as liquid crystal display devices and organic light emitting display devices, is increasing.

The display device may operate at a relatively fast response speed, and it may be desirable for the display device to display input image data without errors even under the relatively fast response speed.

The above information disclosed in this Background section is for enhancement of understanding of the background of the present disclosure, and therefore, it may contain information that does not constitute prior art.

### SUMMARY

Embodiments of the present disclosure may be directed to pixels, a display device including the pixels, and a display system including the pixels, which may be suitable for displaying an image with improved reliability.

According to one or more embodiments of the present disclosure, a pixel of a display device includes: a first transistor connected between a first node and a second node, and including a gate electrode connected to a third node, the first node being connected to a first power supply voltage node; a second transistor connected between a data line and the third node, and including a gate electrode connected to a first sub-gate line; a third transistor connected between a reference voltage node and the third node, and including a gate electrode connected to a second sub-gate line; a first capacitor connected between the third node and a fourth node; a fourth transistor connected between the second node and the fourth node, and including a gate electrode connected to a first sub-light emitting control line; and a light emitting element connected between the fourth node and a second power supply voltage node.

In an embodiment, the first transistor, the second transistor, and the third transistor may be N-type transistors; and the fourth transistor may be a P-type transistor.

In an embodiment, each of the first transistor, the second transistor, and the third transistor may include an oxide semiconductor; and the fourth transistor may include a low temperature polysilicon (LTPS) transistor.

In an embodiment, the pixel may further include a fifth transistor connected between the fourth node and an anode electrode of the light emitting element, and including a gate electrode connected to a second sub-light emitting control line different from the first sub-light emitting control line.

In an embodiment, the first transistor, the second transistor, and the third transistor may be N-type transistors; and the fourth transistor and the fifth transistor may be P-type transistors.

In an embodiment, the first transistor, the second transistor, the third transistor, and the fifth transistor may be N-type transistors; and the fourth transistor may be a P-type transistor.

In an embodiment, the pixel may further include a sixth transistor connected between the anode electrode of the light emitting element and an initialization voltage node, and including a gate electrode connected to a third sub-gate line.

In an embodiment, the pixel may further include a seventh transistor connected between the first power supply voltage node and the first node, and including a gate electrode connected to the first sub-light emitting control line.

In an embodiment, the pixel may further include a second capacitor connected between the fourth node and the first power supply voltage node.

In an embodiment, the pixel may further include a second capacitor connected between the fourth node and the reference voltage node.

According to one or more embodiments of the present disclosure, a display device including: pixels connected to gate lines and light emitting control lines; a gate driver configured to control the gate lines; and an emission driver configured to control the light emitting control lines. A first pixel of the pixels includes: a first transistor connected between a first node and a second node, and including a gate electrode connected to a third node, the first node being connected to a first power supply voltage node; a second transistor connected between a data line and the third node, and including a gate electrode connected to a first sub-gate line of one of the gate lines; a third transistor connected between a reference voltage node and the third node, and including a gate electrode connected to a second sub-gate line of the one of the gate lines; a first capacitor connected between the third node and a fourth node; a fourth transistor connected to the second node, and including a gate electrode connected to a first sub-light emitting control line of one of the light emitting control lines; and a light emitting element connected between the fourth node and a second power supply voltage node.

In an embodiment, the first pixel may further include: a fifth transistor connected between the fourth node and an anode electrode of the light emitting element, and including a gate electrode connected to a second sub-light emitting control line of the one of the light emitting control lines; and a sixth transistor connected between the anode electrode of the light emitting element and an initialization voltage node, and including a gate electrode connected to a third sub-gate line of the one of the gate lines.

In an embodiment, the first pixel may further include a seventh transistor connected between the first power supply voltage node and the first node, and including a gate electrode connected to the first sub-light emitting control line.

In an embodiment, a first period, a second period, a third period, a fourth period, and a fifth period may be sequentially provided. The emission driver may be configured to: apply a first sub-light emitting control signal of a gate on voltage to the first sub-light emitting control line in the second period and the fifth period to turn on the fourth and seventh transistors; and apply a second sub-light emitting control signal of a gate on voltage to the second sub-light emitting control line in the first period, the fourth period, and the fifth period to turn on the fifth transistor. The gate driver may be configured to: apply a first sub-scan signal of a gate on voltage to the first sub-gate line in the third period to turn on the second transistor; apply a second sub-scan signal of a gate on voltage to the second sub-gate line in the first period and the second period to turn on the third transistor; and apply a third sub-scan signal of a gate on voltage to the third sub-gate line in the first to fourth periods to turn on the sixth transistor.

In an embodiment, the third period may include two horizontal periods.

In an embodiment, the display device may further include a data driver connected to the pixels via data lines, the first pixel of the pixels may be connected to one of the data lines, and the data driver may be configured to apply, in the third period, a first data signal corresponding to the first pixel and a second data signal corresponding to a second pixel of the pixels to the one of the data lines.

In an embodiment, the pixels may include a plurality of pixel rows; the first pixel of the pixels may be included in a first pixel row of the plurality of pixel rows; and the second pixel may be included in a second pixel row adjacent to the first pixel row of the plurality of pixel rows.

According to one or more embodiments of the present disclosure, a display system includes: a processor; and a display device including pixels, and configured to display an image in the pixels under a control of the processor. A first pixel of the pixels includes: a first transistor connected between a first node and a second node, and including a gate electrode connected to a third node, the first node being connected to a first power supply voltage node; a second transistor connected between a data line and the third node, and including a gate electrode connected to a first sub-gate line; a third transistor connected between a reference voltage node and the third node, and including a gate electrode connected to a second sub-gate line; a first capacitor connected between the third node and a fourth node; a fourth transistor connected between the second node and the fourth node, and including a gate electrode connected to a first sub-light emitting control line; and a light emitting element connected between the fourth node and a second power supply voltage node.

In an embodiment, the first pixel may further include a fifth transistor connected between the fourth node and an anode electrode of the light emitting element, and including a gate electrode connected to a second sub-light emitting control line different from the first sub-light emitting control line; and a sixth transistor connected between the anode electrode of the light emitting element and an initialization voltage node, and including a gate electrode connected to a third sub-gate line.

In an embodiment, the first pixel may further include a seventh transistor connected between the first power supply voltage node and the first node, and including a gate electrode connected to the first sub-light emitting control line.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram of a display device according to an embodiment.

FIG. 2 is a block diagram illustrating any one of the pixels of FIG. 1 according to an embodiment.

FIG. 3 is a block diagram of a gate driver and an emission driver of FIG. 1 according to an embodiment.

FIG. 4 is a circuit diagram of the pixel in FIG. 2 according to an embodiment.

FIG. 5 is a timing diagram illustrating signals applied to the pixel of FIG. 4 according to an embodiment.

FIGS. 6-8 are diagrams illustrating operations of a pixel in first through third periods of FIG. 5.

FIG. 9 is a timing diagram illustrating a first sub-scan signal and a data voltage in the third period of FIG. 8.

FIG. 10 is a diagram conceptually illustrating an example of a data voltage that may be applied to each pixel.

FIGS. 11 and 12 are diagrams illustrating operations of a pixel in fourth and fifth periods of FIG. 5.

FIG. 13 is a circuit diagram of the pixel in FIG. 2 according to an embodiment.

FIG. 14 is a circuit diagram of the pixel of FIG. 2 according to an embodiment.

FIG. 15 is a timing diagram illustrating signals applied to the pixel of FIG. 14 according to an embodiment.

FIG. 16 is a circuit diagram of the pixel in FIG. 2 according to an embodiment.

FIG. 17 is a circuit diagram of the pixel in FIG. 2 according to an embodiment.

FIG. 18 is a circuit diagram of the pixel in FIG. 2 according to an embodiment.

FIG. 19 is a circuit diagram of the pixel in FIG. 2 according to an embodiment.

FIG. 20 is a circuit diagram of the pixel in FIG. 2 according to an embodiment.

FIG. 21 is a circuit diagram of the pixel of FIG. 2 according to an embodiment.

FIG. 22 is a timing diagram illustrating signals applied to the pixel of FIG. 21 according to an embodiment.

FIG. 23 is a circuit diagram of the pixel in FIG. 2 according to an embodiment.

FIG. 24 is a block diagram of a display system including the display device of FIG. 1 according to an embodiment.

FIG. 25 is a perspective view illustrating an example of a smartphone that may be implemented using the display system of FIG. 24.

FIG. 26 is a perspective view illustrating an example of a tablet computer that may be implemented using the display system of FIG. 24.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

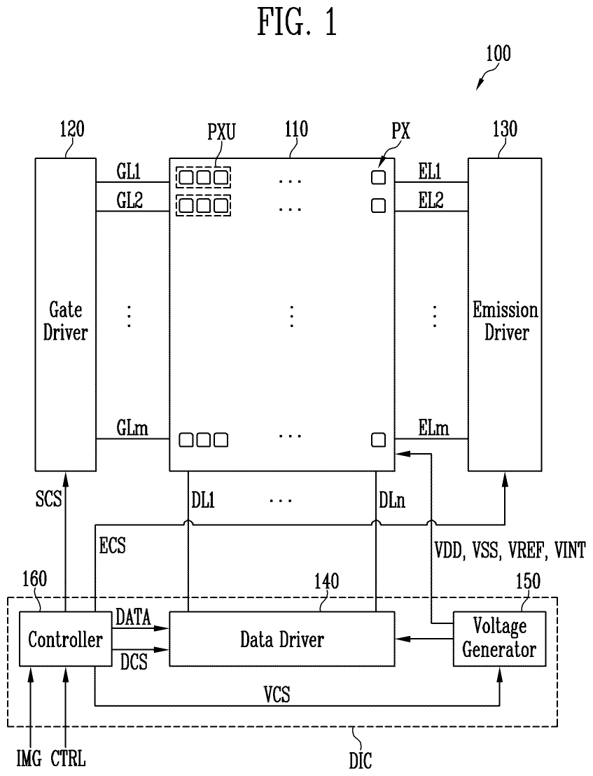

FIG. 1 is a block diagram of a display device according to an embodiment.

Referring to FIG. 1, the display device 100 may include a display panel 110, a gate driver 120, an emission driver 130, a data driver 140, a voltage generator 150, and a controller 160.

The display panel 110 includes pixels PX. The pixels PX may be connected to the gate driver 120 through first to m-th gate lines GL1 to GLm, where m may be a natural number greater than 1. The pixels PX may be connected to the emission driver 130 through first to m-th light emitting control lines EL1 to ELm. The pixels PX may be connected to data driver 140 via first to n-th data lines DL1 to DLn, where n may be a natural number greater than 1.

Each of the pixels PX may include at least one light emitting element to generate light. Accordingly, each of the pixels PX may produce light of one of a variety of suitable colors, such as red, green, blue, cyan, magenta, yellow, or the like. Two or more pixels PX may constitute a pixel unit PXU. For example, as shown in FIG. 1, three pixels PX may constitute a pixel unit PXU.

The gate driver 120 is connected to the pixels PX arranged in a row direction through the first to m-th gate lines GL1 to GLm. The pixels PX arranged in the row direction constitute a pixel row, and the gate driver 120 may be connected to the pixel row through a gate line. The gate driver 120 may output a scan signal to the first to m-th gate lines GL1 to GLm in response to a scan control signal SCS. In some embodiments, each gate line may include a plurality of sub-gate lines through which sub-scan signals may be output. In such cases, the scan signal may be understood to include sub-scan signals. In some embodiments, the scan control signal SCS may include clock signals, and a scan start signal indicating the start of each frame.

The emission driver 130 is connected to the pixels PX arranged in the row direction through the first to m-th light emitting control lines EL1 to ELm. The emission driver 130 may be connected to the pixel row through a light emitting control line. The emission driver 130 may output a light emitting control signal to the first to m-th light emitting control lines EL1 to ELm in response to light emitting control signals ECS. Each light emitting control line may include a plurality of sub-light emitting control lines, and sub-light emitting control signals may be output through the plurality of sub-light emitting control lines. In this case, the light emitting control signal may be understood to include sub-light emitting control signals. In embodiments, the light emitting control signal ECS may include clock signals, and a light emitting start signal indicating the start of each frame.

The gate driver 120 may be disposed on one side of the display panel 110, and the emission driver 130 may be disposed on another side (e.g., an opposite side) of the display panel 110 opposite to the one side of the display panel 110. However, the present disclosure is not limited thereto. The gate driver 120 and the emission driver 130 may be disposed around the display panel 110 in various suitable forms.

The data driver 140 is connected to the pixels PX arranged in a column direction through the first to n-th data lines DL1 to DLn. The pixels PX arranged in the column direction constitute a pixel column, and the data driver 140 may be connected to the pixel column through a data line. The data driver 140 receives image data DATA and a data control signal DCS from the controller 160. The data driver 140 operates in response to the data control signal DCS. In some embodiments, the data control signal DCS may include clock signals, a start pulse, and the like.

The data driver 140 may use voltages from the voltage generator 150 to apply data voltages (e.g., data signals) having grayscale values corresponding to the image data DATA to the first to n-th data lines DL1 to DLn. When the scan signal is applied to each of the first to m-th gate lines GL1 to GLm, the data voltages corresponding to the image data DATA may be applied to the first to n-th data lines DL1 to DLn. Accordingly, corresponding pixels PX may emit light corresponding to the data voltages, and an image may be displayed on the display panel 110.

The voltage generator 150 may operate in response to a voltage control signal VCS from the controller 160. The voltage generator 150 may generate a plurality of voltages, and may provide the generated voltages to the components of the display device 100. For example, the voltage generator 150 may generate a plurality of voltages by receiving an input voltage from outside the display device 100, adjusting the received voltage, and regulating the adjusted voltage.

The voltage generator 150 may generate a first power supply voltage VDD, a second power supply voltage VSS, a reference voltage VREF, and an initialization voltage VINT, which may be provided to the pixels PX. However, the present disclosure is not limited thereto. For example, at least one of the first power supply voltage VDD, the second power supply voltage VSS, the reference voltage VREF, and/or the initialization voltage VINT may be provided by an external device of the display device 100.

The first power supply voltage VDD may have a relatively higher voltage level. The reference voltage VREF may have a voltage level lower than that of the first power supply voltage VDD, and the second power supply voltage VSS may have a voltage level lower than that of the reference voltage VREF. For example, the second power supply voltage VSS may have a negative voltage level. The initialization voltage VINT may have a voltage level between those of the reference voltage VREF and the second power supply voltage VSS, may have a voltage level equal to that of the second power supply voltage VSS, or may have a voltage level lower than that of the second power supply voltage VSS.

The controller 160 controls various operations of the display device 100. The controller 160 receives the input image data IMG and the control signal CTRL for controlling the display of the display device 100 from the outside. The controller 160 may generate the scan control signal SCS, the light emitting control signal ECS, the data control signal DCS, and the voltage control signal VCS, in response to the control signal CTRL.

The controller 160 may convert the input image data IMG to be suitable for the display device 100 or the display panel 110, and may output the image data DATA to the data driver 140. For example, the controller 160 may sort the input image data IMG according to an arrangement of the pixels PX to output the image data DATA.

Two or more components of the data driver 140, the voltage generator 150, and the controller 160 may be mounted in one integrated circuit. As shown in FIG. 1, the data driver 140, the voltage generator 150, and the controller 160 may be included in a driver integrated circuit DIC. In this case, the data driver 140, the voltage generator 150, and the controller 160 may be functionally distinct components within the driver integrated circuit DIC. In other embodiments, at least one of the data driver 140, the voltage generator 150, and/or the controller 160 may be provided as a component separate from the driver integrated circuit DIC.

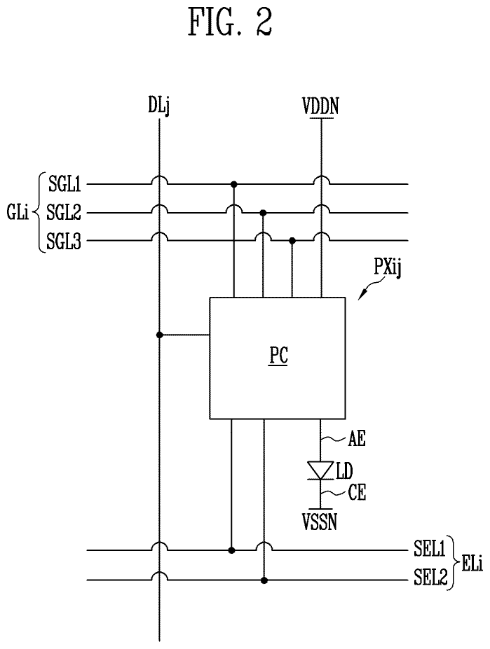

FIG. 2 is a block diagram illustrating any one of the pixels of FIG. 1 according to an embodiment.

In FIG. 2, among the pixels PX in FIG. 1, a pixel PXij arranged in an i-th row (where i is an integer greater than or equal to 1 and less than or equal to m) and a j-th column (where j is an integer larger than or equal to 1 and less than or equal to n) is shown as a representative example.

Referring to FIG. 2, the pixel PXij may include a pixel circuit PC and a light emitting element LD.

The light emitting element LD is connected between a first power supply voltage node VDDN and a second power supply voltage node VSSN. In this case, the first supply voltage node VDDN is a node to which the first supply voltage VDD of FIG. 1 is applied, and the second supply voltage node VSSN is a node which is applied with the second supply voltage VSS of FIG. 1.

An anode electrode AE of the light emitting element LD may be connected to the first power supply voltage node VDDN via the pixel circuit PC. A cathode electrode CE of the light emitting element LD may be connected to the second power supply voltage node VSSN. For example, the anode electrode AE of the light emitting element LD may be connected to the first power supply voltage node VDDN via one or more transistors included in the pixel circuit PC.

As described above, the pixel PXij is arranged in the i-th row and the j-th column from among the pixels PX of FIG. 1. The pixel circuit PC may be connected to an i-th gate line GLi among the first to m-th gate lines GL1 to GLm of FIG. 1, an i-th light emitting control line ELi among the first to n-th light emitting control lines EL1 to ELm of FIG. 1, and a j-th data line DLj among the first to the n-th data lines DL1 to DLn of FIG. 1. The pixel circuit PC may control the light emitting element LD according to signals received through the signal lines.

The i-th gate line GLi may include first to third sub-gate lines SGL1 to SGL3. The pixel circuit PC may operate in response to first to third sub-scan signals received via the first to third sub-gate lines SGL1 to SGL3.

The i-th light emitting control line ELi may include first and second sub-light emitting control lines SEL1 and SEL2. The pixel circuit PC may operate in response to first and second sub-light emitting control signals received via the first and the second sub-light emitting control lines SEL1 and SEL2.

The pixel circuit PC may receive the data voltage through the j-th data line DLj. The pixel circuit PC may store the data voltage in response to at least one of the sub-scan signals received through the first to third sub-gate lines SGL1 to SGL3. The pixel circuit PC may adjust a current flowing from the first power supply voltage node VDDN to the second power supply voltage node VSSN through the light emitting element LD, according to a stored data voltage in response to at least one of the sub-light emitting control signals received through the first and second sub-light-emitting control lines SEL1 and SEL2. Accordingly, the light emitting element LD may emit light having a luminance corresponding to the data voltage.

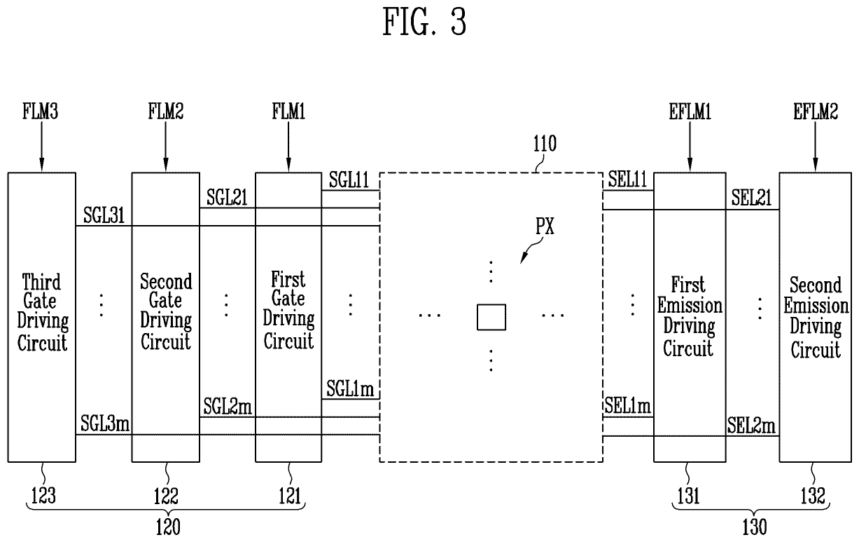

FIG. 3 is a block diagram of the gate driver and the emission driver of FIG. 1 according to an embodiment.

Referring to FIG. 3, the gate driver 120 may include a first gate driving circuit 121, a second gate driving circuit 122, and a third gate driving circuit 123.

The first gate driving circuit 121 receives a first scan start signal FLM1. The first gate driving circuit 121 may generate a first sub-scan signal while shifting the first scan start signal FLM1 in response to a clock signal. The first gate driving circuit 121 may sequentially supply the first sub-scan signal to first sub-gate lines SGL11 to SGL1m. The i-th sub-gate line SGL1i of the first sub-gate lines SGL11 to SGL1m may be the first sub-gate line SGL1 of the i-th gate line GLi of FIG. 2.

The second gate driving circuit 122 receives a second scan start signal FLM2. The second gate driving circuit 122 may generate a second sub-scan signal while shifting the second scan start signal FLM2 in response to the clock signal. The second gate driving circuit 122 may sequentially supply the second sub-scan signal to second sub-gate lines SGL21 to SGL2m. The i-th sub-gate line SGL2i of the second sub-gate lines SGL21 to SGL2m may be the second sub-gate line SGL2 of the i-th gate line GLi of FIG. 2.

The third gate driving circuit 123 receives a third scan start signal FLM3. The third gate driving circuit 123 may generate a third sub-scan signal while shifting the third scan start signal FLM3 in response to the clock signal. The third gate driving circuit 123 may sequentially supply the third sub-scan signal to third sub-gate lines SGL31 to SGL3m. The i-th sub-gate line SGL3i of the third sub-gate lines SGL31 to SGL3m may be the third sub-gate line SGL3 of the i-th gate line GLi of FIG. 2.

A first emission driving circuit 131 receives a first light emitting start signal EFLM1. The first emission driving circuit 131 may generate a first sub-light emitting control signal while shifting the first light emitting start signal EFLM1 in response to the clock signal. The first emission driving circuit 131 may sequentially supply the first sub-light emitting control signal to first sub-emitting control lines SEL11 to SEL1m. The i-th sub-light emitting control line SEL1i among the first sub-light emitting controls SEL11 to SEL1m may be the first sub-light emitting control line SEL1 of the i-th light emitting control line ELi of FIG. 2.

The second emission driving circuit 132 receives a second light emitting start signal EFLM2. The second emission driving circuit 132 may generate a second sub-light emitting control signal while shifting the second light emitting start signal EFLM2 in response to the clock signal. The second emission driving circuit 132 may sequentially supply the second sub-light emitting control signal to second sub-emitting control lines SEL21 to SEL2m. The i-th sub-light emitting control line SEL2i of the second sub-light emitting controls SEL21 to SEL2m may be the second sub-light emitting control line SEL2 of the i-th light emitting control line ELi of FIG. 2.

The first to third scan start signals FLM1 to FLM3 may be included in the scan control signal SCS of FIG. 1. The scan control signal SCS may further include clock signals provided to the first to third gate driving circuits 121 to 123. The first and second light emitting start signals EFLM1 and EFLM2 may be included in the light emitting control signal ECS of FIG. 1. The light emitting control signal ECS may further include clock signals provided to the first and second light emitting driver circuits 131, 132.

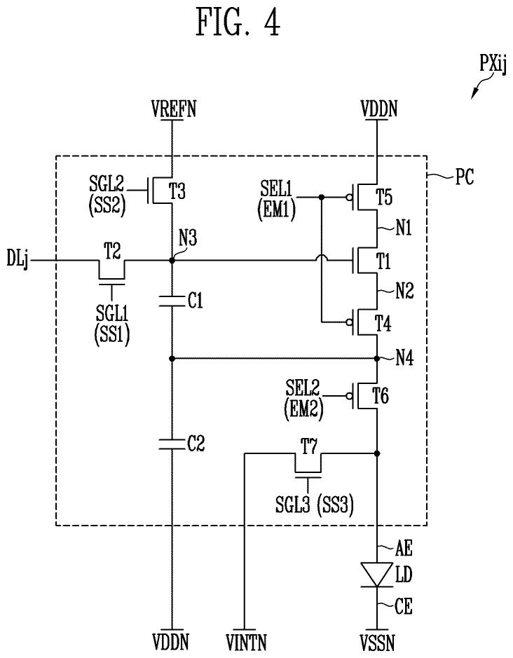

FIG. 4 is a circuit diagram of the pixel in FIG. 2 according to an embodiment.

Referring to FIG. 4, the pixel PXij includes a pixel circuit PC and a light emitting element LD.

The light emitting element LD may include an anode electrode AE, a cathode electrode CE, and a light emitting layer. The light emitting layer may be physically disposed between the anode electrode AE and the cathode electrode CE. The light emitting layer may emit light according to an amount of current flowing from the anode electrode AE through the light emitting layer to the cathode electrode CE. The anode electrode AE of the light emitting element LD may be electrically connected to the first power supply voltage node VDDN via the pixel circuit PC. The cathode electrode CE of the light emitting element LD may be electrically connected to the second power supply voltage node VSSN. The light emitting element LD may emit light according to the amount of current flowing from the first power supply voltage node VDDN to the second power supply voltage node VSSN through the pixel circuit PC.

The light emitting element LD may include an organic light emitting diode. However, the present disclosure is not limited thereto. For example, the light emitting element LD may include an inorganic light emitting diode. For example, the light emitting element LD may include both an organic substance and an inorganic substance. Although the pixel PXij is illustrated as including one light emitting element LD in FIG. 4, the pixel PXij may include two or more light emitting elements. In this case, the two or more light emitting elements may be connected to each other in series or in parallel.

The pixel circuit PC may include first to seventh transistors T1 to T7 and a first capacitor C1.

The first transistor T1, the second transistor T2, the third transistor T3, and the seventh transistor T7 may be N-type transistors. For example, the first transistor T1, the second transistor T2, the third transistor T3, and the seventh transistor T7 may be N-channel metal oxide semiconductor (NMOS) transistors.

The fourth transistor T4, the fifth transistor T5, and the sixth transistor T6 may be P-type transistors. For example, the fourth transistor T4, the fifth transistor T5, and the sixth transistor T6 may be P-channel Metal Oxide Semiconductor (PMOS) transistors.

The first transistor T1 includes a drain electrode connected to a first node N1, a source electrode connected to a second node N2, and a gate electrode connected to a third node N3. The first transistor T1 may be turned on in response to a voltage difference between the drain electrode and the source electrode. The first power supply voltage VDD of FIG. 1 is transmitted to the first power supply voltage node VDDN. The second power supply voltage VSS of FIG. 1 is transmitted to the second power supply voltage node VSSN. The second power supply voltage VSS may have a lower level than that of the first power supply voltage VDD. When the fourth to sixth transistors T4 to T6 are turned on, the first transistor T1 may control the amount of current flowing from the first power supply voltage node VDDN to the second power supply voltage node VSSN through the light emitting element LD according to a voltage difference between the third node N3 and a fourth node N4.

The first transistor T1 may be an N-type transistor.

The second transistor T2 is connected between the data line DLj and the third node N3. The gate electrode of the second transistor T2 is connected to the first sub-gate line SGL1. The second transistor T2 may be turned on when the first sub-scan signal SS1 of a gate on voltage is applied to the first sub-gate line SGL1, so as to electrically connect the data line DLj and the third node N3 to each other. Accordingly, the data voltage of the data DLj may be transferred to the third node N3.

The second transistor T2 may be an N-type transistor. Accordingly, the gate on voltage of the first sub-scan signal SS1 may correspond to a logic high level.

The third transistor T3 is connected between a reference voltage node VREFN and the third node N3. The gate electrode of the third transistor T3 is connected to the second sub-gate line SGL2. The third transistor T3 may be turned on when the second sub-scan signal SS2 of the gate on voltage is applied to the second sub-gate line SGL2, so as to electrically connect the third node N3 to the reference voltage node VREFN. The reference voltage VREF in FIG. 1 is applied to the reference voltage node VREFN. Accordingly, the reference voltage VREF may be transmitted to the third node N3 when the third transistor T3 is turned on.

The third transistor T3 may be an N-type transistor. Accordingly, the gate on voltage of the second sub-scan signal SS2 may be provided at a logic high level.

According to an embodiment, the fourth transistor T4 is provided between the second node N2 and the fourth node N4. The gate electrode of the fourth transistor T4 is connected to the first sub-light emitting control line SEL1. The fourth transistor T4 may be turned off when the first sub-light emitting control signal EM1 of a gate off voltage is applied to the first sub-light emitting control line SEL1, so as to electrically separate the fourth node N4 from the second node N2. The fourth transistor T4 is turned on when the first sub-light emitting control signal EM1 of the gate on voltage is applied to the first sub-light emitting control line SEL1, so that the second node N2 and the fourth node N4 may be electrically connected to each other.

The fourth transistor T4 may be a P-type transistor. Accordingly, the gate on voltage of the first sub-light emitting control signal EM1 may be provided at a logic low level.

If the fourth transistor T4 is not provided, the fourth node N4 is directly connected to the source electrode of the first transistor T1 or the second node N2, regardless of the first sub-light emitting control signal EM1. In this case, when the first transistor T1 is turned on under an influence of the data voltage corresponding to a pixel PX(i−1) j of a previous pixel row, the voltage of the fourth node N4 may be changed unintentionally by charges of the first node N1. Accordingly, the pixel PXij may emit light unintentionally under the influence of the data voltage corresponding to the pixel PX(i−1) j in the previous pixel row. As such, each pixel row may display an unintended image under an influence of the data voltages corresponding to a previous pixel row.

According to an embodiment, the fourth transistor T4 is provided between the second node N2 and the fourth node N4, and the fourth transistor T4 may prevent or substantially prevent the voltage of the fourth node N4 from being affected by the data voltage corresponding to the pixel PX(i−1) j of the previous pixel row. Accordingly, each pixel row may display an intended image without being affected by the data voltages corresponding to a previous pixel row. Therefore, the image displayed by the display device 100 may have a high reliability.

The fifth transistor T5 is connected between the first power supply voltage node VDDN and the first node N1. The gate electrode of the fifth transistor T5 is connected to the first sub-light emitting control line SEL1. In other words, the gate electrodes of the fourth and fifth transistors T4 and T5 may be connected in common to the first sub-light emitting control line SEL1. The fifth transistor T5 may be turned on when the first sub-light emitting control signal EM1 of the gate on voltage is applied to the first sub-light emitting control line SEL1, to connect the first node N1 to the first power supply voltage node VDDN. Accordingly, the first power supply voltage VDD may be transmitted to the first node N1 when the fifth transistor T5 is turned on.

The fifth transistor T5 may be a P-type transistor.

The sixth transistor T6 is connected between the fourth node N4 and the anode electrode AE. The gate electrode of the sixth transistor T6 is connected to the second sub-light emitting control line SEL2. The sixth transistor T6 may be turned on when the second sub-light emitting control signal EM of the gate on voltage is applied to the second sub-light emitting control line SEL2.

The sixth transistor T6 may be a P-type transistor. Accordingly, the gate on voltage of the second sub-light emitting control signal EM2 may be provided at a logic low level.

The seventh transistor T7 is connected between the anode electrode AE and an initialization voltage node VINTN. The gate electrode of the seventh transistor T7 is connected to the third sub-gate line SGL3. The seventh transistor T7 may be turned on when the third sub-scan signal SS3 of the gate on voltage is applied to the third sub-gate line SGL3, thereby connecting the anode electrode AE to the initialization voltage node VINTN. The initialization voltage VINT in FIG. 1 is transmitted to the initialization voltage node VINTN. Accordingly, when the seventh transistor T7 is turned on, the initialization voltage VINT may be transferred to the anode electrode AE.

The seventh transistor T7 may be an N-type transistor. Accordingly, the gate on voltage of the third sub-scan signal SS3 may be provided at a logic high level.

The first power supply voltage VDD may have a relatively higher voltage level. The reference voltage VREF may have a voltage level lower than that of the first power supply voltage VDD, and the second power supply voltage VSS may have a voltage level lower than that of the reference voltage VREF. For example, the second power supply voltage VSS may have a negative voltage level. The initialization voltage VINT may have a voltage level between those of the reference voltage VREF and the second power supply voltage VSS, may have a voltage level equal to that of the second power supply voltage VSS, or may have a voltage level lower than that of the second power supply voltage VSS.

The first capacitor C1 is connected between the third node N3 and the fourth node N4. The first capacitor C1, or the third node N3 that is one end of the first capacitor C1, may store the data voltage provided through the data line DLj.

The pixel circuit PC may further include a second capacitor C2. The second capacitor C2 is connected between the fourth node N4 and the first power supply voltage node VDDN.

In some embodiments, the first, second, third, and seventh transistors T1, T2, T3, and T7 may be N-type transistors and oxide thin film transistors including an oxide semiconductor. In some embodiments, the fourth to sixth transistors T4 to T6 may be P-type transistors and low temperature polysilicon (LTPS) transistors.

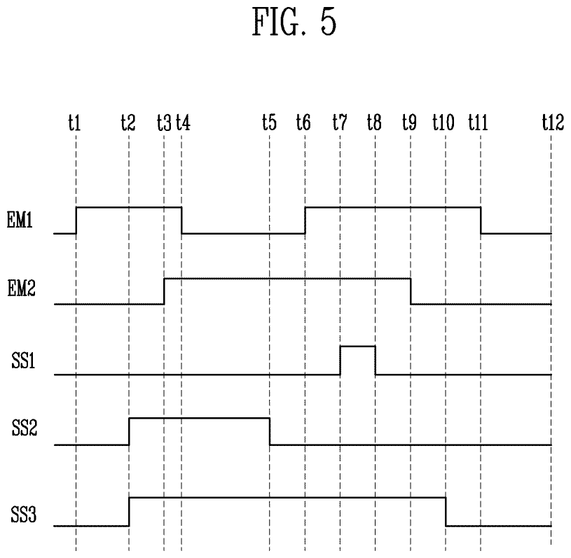

FIG. 5 is a timing diagram illustrating signals applied to the pixel of FIG. 4 according to an embodiment.

Referring to FIGS. 4 and 5, at a first time t1, the first sub-light emitting control signal EM1 transitions to the gate off voltage. In response to the first sub-light emitting control signal EM1, the fourth and fifth transistors T4 and T5 may be turned off.

At a second time t2, the second sub-scan signal SS2 and the third sub-scan signal SS3 transition to the gate on voltage. The second sub-light emitting control signal EM2 has the gate on voltage before the third time t3. Accordingly, the third, sixth, and seventh transistors T3, T6, and T7 may be turned on. The third node N3 may be initialized to the reference voltage VREF of the reference voltage node VREFN. The anode electrode AE and the fourth node N4 may be initialized with the initialization voltage VINT of the initialization voltage node VINTN.

At a third time t3, the second sub-light emitting control signal EM2 transitions to the gate off voltage. Accordingly, the sixth transistor T6 is turned off while the seventh transistor T7 continues to be turned on, and the anode electrode AE may continue to receive the initialization voltage VINT.

At a fourth time t4, the first sub-light emitting control signal EM1 transitions to the gate on voltage. In response to the first sub-light emitting control signal EM1, the fourth and fifth transistors T4 and T5 may be turned on. Because the voltage of the third node N3 has been initialized to the reference voltage VREF, the first transistor T1 may be turned on. Accordingly, the fourth node N4 may be electrically connected to the first power supply voltage node VDDN via the first, fourth, and fifth transistors T1, T4, and T5, which are turned on. The voltage of the fourth node N4 may increase so that a voltage difference between the third node N3 and the fourth node N4 becomes a threshold voltage of the first transistor T1.

At a fifth time t5, the second sub-scan signal SS2 transitions to the gate off voltage. Accordingly, the third transistor T3 may be turned off.

At a sixth time t6, the first sub-light emitting control signal EM1 transitions to the gate off voltage. Accordingly, the fourth and fifth transistors T4 and T5 may be turned off.

At a seventh time t7, the first sub-scan signal SS1 transitions to the gate on voltage, and at an eighth time t8, the first sub-scan signal SS1 transitions to the gate off voltage. The second transistor T2 may be turned on, and the data voltage of the data line DLj may be stored at the third node N3. The amount of voltage change of the third node N3 may be transferred to the fourth node N4 according to the first and second capacitors C1 and C2.

At a ninth time t9, the second sub-light emitting control signal EM2 may transition to the gate on voltage to turn on the sixth transistor T6. The third sub-scan signal SS3 has a turn-on voltage from the second time t2 to a tenth time t10, so that the seventh transistor T7 is turned on. Accordingly, the fourth node N4 may be initialized with the initialization voltage VINT. The amount of voltage change of the fourth node N4 may be transferred to the third node N3 according to the first and second capacitors C1 and C2.

At the tenth time t10, the third sub-scan signal SS3 transitions to the gate off voltage. Accordingly, the seventh transistor T7 may be turned off. The anode electrode AE is electrically isolated from the initialization voltage node VINTN.

At an eleventh time t11, the first sub-light emitting control signal EM1 transitions to the gate on voltage. The first and second sub-light emitting control signals EM1 and EM2 have the gate on voltage until a twelfth time t12. Accordingly, the fourth to sixth transistors T4 to T6 may be turned on. The first transistor T1 may be turned on according to a voltage difference between the gate electrode and the source electrode thereof. The first transistor T1 may adjust a current flowing from the first power supply voltage node VDDN to the second power supply voltage node VSSN through the light emitting element LD according to a voltage difference between the third and fourth nodes N3 and N4.

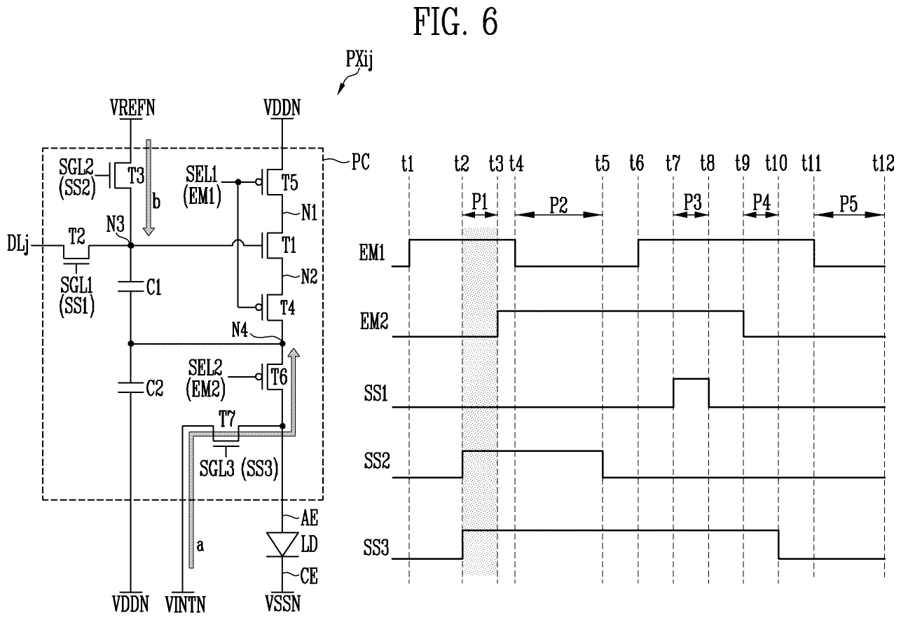

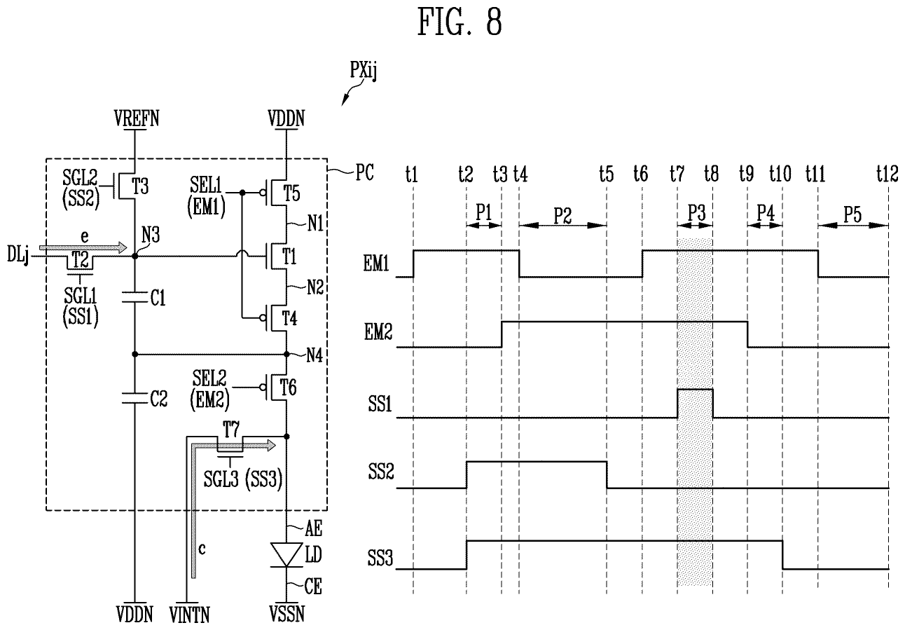

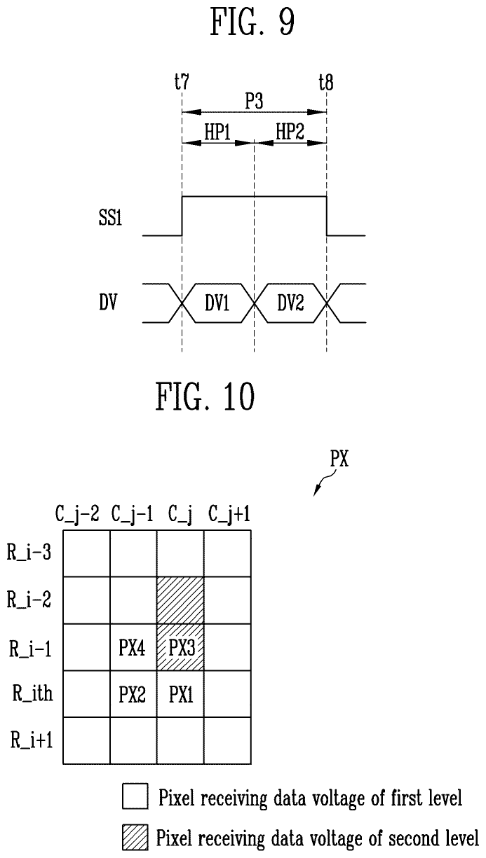

FIGS. 6 through 8 are diagrams illustrating operations of a pixel in first through third periods of FIG. 5. FIG. 9 is a timing diagram illustrating the first sub-scan signal and the data voltage in the third period of FIG. 8. FIG. 10 is a diagram conceptually illustrating an example of a data voltage that may be applied to each pixel.

Referring to FIG. 6, in a first period P1 between the second and third times t2 and t3, the first sub-light emitting control signal EM1 may have (e.g., may be set to) the gate off voltage, the second sub-light emitting control signal EM2 may have (e.g., may be set to) the gate on voltage, the first sub-scan signal SS1 may have (e.g., may be set as) the gate off voltage, and the second and third sub-scan signals SS2 and SS3 may have (e.g., may be set as) the gate on voltage. Accordingly, the initialization voltage VINT of FIG. 1 of the initialization voltage node VINTN may be transferred to the anode electrode AE and the fourth node N4 via the turned on sixth and seventh transistors T6, T7 (e.g., see a). The reference voltage VREF of FIG. 1 of the reference voltage node VREFN may be transmitted to the third node N3 via the turned-on third transistor T3 (e.g., see b). As such, in the first period P1, the voltages of the anode electrode AE and the fourth node N4 are initialized to the initialization voltage VINT, and the voltage of the third node N3 is initialized to the reference voltage VREF.

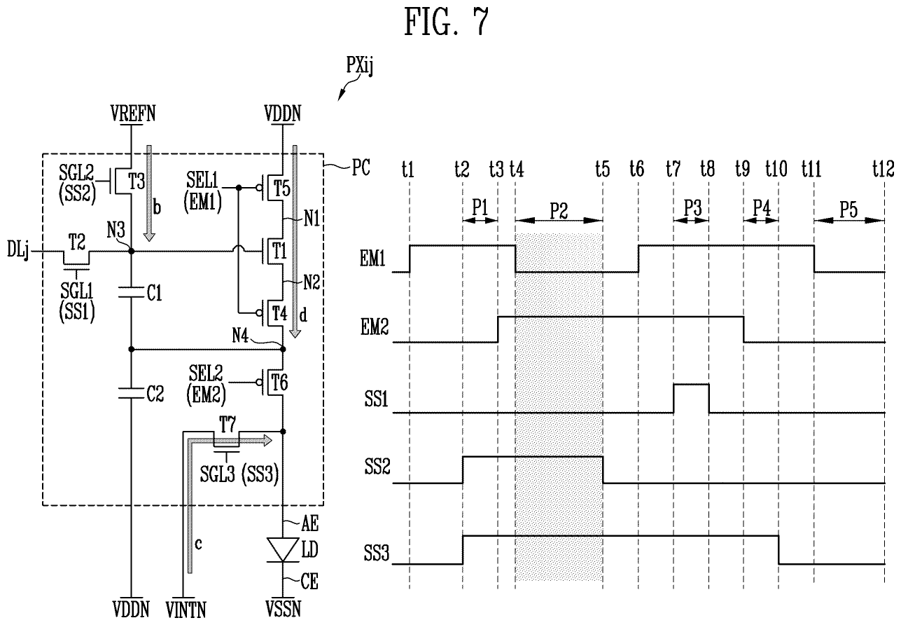

Referring to FIG. 7, in a second period P2 between the fourth and fifth times t4 and t5, the first sub-light emitting control signal EM1 may have (e.g., may be set to) the gate on voltage, the second sub-light emitting control signal EM2 may have (e.g., may be set to) the gate off voltage, the first sub-scan signal SS1 may have (e.g., may be set to) the gate off voltage, and the second and third sub-scan signals SS2 and SS3 may have (e.g., may be set to) the gate on voltage. The anode electrode AE continues to receive the initialization voltage VINT via the turned-on seventh transistor T7 (e.g., see c). On the other hand, the fourth node N4 is blocked from the initialization voltage VINT due to the turned-off sixth transistor T6.

The fourth and fifth transistors T4 and T5 may be turned on in response to the first sub-light emitting control signal EM1. The first transistor T1 may be turned on in response to the reference voltage VREF applied to the third node N3. The first power supply voltage VDD of FIG. 1 of the first power supply voltage node VDDN may be applied to the fourth node N4 via the fifth transistor T5, the first transistor T1, and the fourth transistor T4 (e.g., see d).

The third node N3 may correspond to the gate electrode of the first transistor T1. The fourth node N4 is connected to the source electrode (e.g., the second node N2) of the first transistor T1 through the turned-on fourth transistor T4, so that the fourth node N4 may correspond to the source electrode of the first transistorT1 in the second period P2. In other words, in the second period P2, the third and fourth nodes N3 and N4 may correspond to the gate electrode of the first transistor T1 and the source electrode of the first transistor T1, respectively. Until the voltage difference between the third node N3 and the fourth node N4 corresponds to the threshold voltage of the first transistor T1, the voltage of the fourth node N4 may increase. In other words, the voltage of the fourth node N4 may have (e.g., may be set to) a value obtained by subtracting the threshold voltage of the first transistor T1 from the reference voltage VREF of the third node N3. For example, the voltage of the fourth node N4 may be determined as shown in Equation 1.

$$VsP 2 = VREF - Vth : \qquad Equation 1$$

In Equation 1, VREF denotes the reference voltage VREF, Vth denotes the threshold voltage of the first transistor T1, and VsP2 denotes the voltage of the fourth node N4 in (e.g., set in) the second period P2. As such, the threshold voltage of the first transistor T1 may be reflected in the voltage of the fourth node N4 in the second period P2. In other words, the threshold voltage of the first transistor T1 in the second period P2 may be reflected in the voltage difference between the third and fourth nodes N3 and N4. By reflecting the threshold voltage of the first transistor T1 in the voltage of the fourth node N4, a deviation (e.g., a variation) of the threshold voltages between the first transistors of the pixels may be compensated for.

Referring to FIG. 8, in a third period P3 between the seventh and eighth times t7 and t8, the first and second sub-light emitting control signals EM1 and EM2 have the gate off voltage, the first sub-scan signal SS1 has the gate on voltage, the second sub-scan signal SS2 has the gate off voltage, and the third sub-scan signal SS3 has the gate on voltage.

Because the third transistor T3 is turned off, the third node N3 may be electrically isolated from the reference voltage node VREFN. On the other hand, the third node N3 may receive the data voltage of the data line DLj via the turned-on second transistor T2 (e.g., see e). Accordingly, in the third period P3, the third node N3 may store the data voltage of the data line DLj. The amount of voltage change of the third node N3 may be transferred to the voltage of the fourth node N4 according to the first and second capacitors C1 and C2. For example, the voltage of the fourth node N4 may be determined as shown in Equation 2.

$$VsP 3 = VsP 2 + \frac{C 1}{C 1 + C 2} \times ( D V - VREF ) : \qquad Equation 2$$

In Equation 2, VsP2 denotes the voltage of the fourth node N4 in (e.g., set in) the second period P2, C1 denotes the capacitance of the first capacitor C1, C2 represents the capacitance of second capacitor C2, and DV denotes the data voltage. VsP3 denotes the voltage of the fourth node N4 in (e.g., set in) the third period P3. DV-VREF denotes the voltage change amount of the third node N3 in the third period P3.

The third period P3 may correspond to two horizontal periods. Referring to FIG. 9, the first sub-scan signal SS1 has the gate on voltage for the third period P3, and the third period P3 may overlap with a first horizontal period HP1 and a second horizontal period HP2. Each horizontal period HP1 and HP2 may refer to a period in which data voltages corresponding to one pixel row are applied to the first to nth data lines DL1 to DLn. FIG. 9 shows the data voltage DV applied to the data line DLj. During the first horizontal period HP1, a first data voltage DV1 may be applied to the data line DLj. The first data voltage DV1 corresponds to the pixel PX(i−1) j of a previous pixel row. In other words, the pixels PX(i−1) j in the previous pixel row may emit light according to the first data voltage DV1. During the second horizontal period HP2, a second data voltage DV2 may be applied to the data line DLj. The second data voltage DV2 corresponds to the pixel PXij. In other words, the pixel PXij may emit light according to the second data voltage DV2.

As such, the first sub-scan signal SS1 may have the gate on voltage not only in the second horizontal period HP2, but also in the first horizontal period HP1, which means that the third node N3 of the pixel PXij receives not only the second data voltage DV2, but also the first data voltage DV1. Taking into account the characteristics of the second transistor T2 and/or the characteristics of the third transistor T3, the second sub-scan signal SS2 may have the gate on voltage for a longer period of time including the second horizontal period HP2. For example, as the display device 100 operates at a high speed, the length of each horizontal period HP1 and HP2 may be shortened, and the horizontal period may be shorter than the time used to drive the second and third transistors T2 and T3. For example, when the second and third transistors T2 and T3 are oxide semiconductor transistors, the horizontal period may be shorter than the time used to drive the second and third semiconductor transistors T2 and T3.

The fourth transistor T4 may prevent or substantially prevent the voltage of the fourth node N4 from being affected by the first data voltage DV1 corresponding to the pixel PX(i−1) j in the previous pixel row. This will be described in more detail below with reference to FIG. 10.

Referring to FIG. 10, the pixels PX arranged in i−3-th to i+1-th pixel rows R_i−3 to R_i+1 and j−2-th to j+1-th pixels columns C_j−2 to C_j+1 are illustrated. A data voltage may be applied to each of the pixels PX according to an image displayed on the display panel 110 of FIG. 1. For example, as shown in FIG. 10, a first level of a data voltage may be provided to some of the pixels PX, and a second level of a data voltage lower than the first level may be provided to others of the pixels PX. The pixels PX receiving the first level data voltage may emit light with a higher luminance than those of the pixels PX receiving the second level data voltage. For example, the first level data voltage may correspond to an intermediate grayscale level between a minimum grayscale level and a maximum grayscale level, and the second level data voltage may correspond to the minimum grayscale level.

For convenience of illustration, a pixel PX disposed in the i-th pixel row R_ith and the j-th pixel column C_j is referred to as a first pixel PX1, a pixel PX disposed in the i-th pixel row R_ith and a j−1-th pixel column C_j−1 is referred to as a second pixel PX2, a pixel PX disposed in an i−1-th pixel row R_i−1 and the j-th pixel column C_j is referred to as a third pixel PX3, and a pixel PX disposed in the i−1-th pixel row R_i−1 and the j−1-th pixel column C_j−1 is referred to as a fourth pixel PX4.

Referring to FIG. 10 together with FIGS. 8 and 9, in the first horizontal period HP1, the second level data voltage corresponding to the third pixel PX3 is applied to the data line DLj and received at the third node N3 of the first pixel PX1. In response to the second level data voltage of the third node N3, the first transistor T1 of the first pixel PX1 may be turned off. As the first transistor T1 is turned off, charges that have been transferred from the first power supply voltage node VDDN to the first node N1 and remain may not be transferred to the second node N2. Accordingly, the voltage of the second node N2 of the first pixel PX1 may not change in the first horizontal period HP1. The fourth transistor T4 is turned off, and the voltage of the fourth node N4 may not be affected by the second node N2.

In the second horizontal period HP2, the first level data voltage corresponding to the first pixel PX1 is applied to the data line DLj and received at the third node N3 of the first pixel TX1. In response to the data voltage of the first level of the third node N3, the first transistor T1 of the first pixel PX1 may be turned on. On the other hand, the charges transferred from the first power supply voltage node VDDN in the second period P2 may remain at the first node N1 or a parasitic capacitor connected to the first node N1, respectively. As the first transistor T1 is turned on in the second horizontal period HP2, charges remaining at the first node N1 may be transferred to the second node N2. Accordingly, the voltage of the second node N2 of the first pixel PX1 may change in the second horizontal period HP2. The fourth transistor T4 is turned off, and the voltage of the fourth node N4 may not be affected by the second node N2.

In the first horizontal period HP1, the first level data voltage corresponding to the fourth pixel PX4 is applied to the data line DLj−1 and received at the third node N3 of the second pixel PX2. In response to the first level data voltage of the third node N3, the first transistor T1 of the second pixel PX2 may be turned on. As the first transistor T1 is turned on, charges remaining at the first node N1 may be transferred to the second node N2. Accordingly, the voltage of the second node N2 of the second pixel PX2 may change in the first horizontal period HP1. The fourth transistor T4 is turned off, and the voltage of the fourth node N4 may not be affected by the second node N2.

In the second horizontal period HP2, the first level data voltage corresponding to the second pixel PX2 is applied to the data line DLj−1 and received at the third node N3 of the second pixel TX2. In response to the first level data voltage of the third node N3, the first transistor T1 of the second pixel PX2 may be turned on. As the first transistor T1 is turned on, charges remaining at the first node N1 may be transferred to the second node N2. Accordingly, the voltage of the second node N2 of the second pixel PX2 may change in the second horizontal period HP2. The fourth transistor T4 is turned off, and the voltage of the fourth node N4 may not be affected by the second node N2.

As such, the voltage of the fourth node N4 of each of the first and second pixels PX1 and PX2 may not be affected by the second node N2.

If the fourth transistor T4 is not provided, the fourth node N4 may be directly connected to the second node N2. In this case, the voltage of the fourth node N4 of the first pixel PX1 may change under an influence of the charges of the first node N1 during the second horizontal period HP2. On the other hand, the voltage of the fourth node N4 of the second pixel PX2 may change under an influence of the charges of the first node N1 during the first and second horizontal periods HP1 and HP2. Accordingly, the voltage of the fourth node N4 of the first pixel PX1 may be different from the voltage of the third node N4 of second pixel PX2 after the first and second horizontal periods HP1 and HP2. Each of the first and second pixels PX1 and PX2 stores the data voltage of the first level received in the second horizontal period HP2 in the third node N3. This means that the voltage difference between the third and fourth nodes N3 and N4 of the first pixel PX1 may be different from the voltage difference between third and fourth nodes N3 and N4 of the second pixel PX2. Accordingly, the first and second pixels PX1 and PX2 may emit light having a different luminance from each other, although they should emit light of the same luminance as each other.

According to an embodiment, in each of the first and second pixels PX1 and PX2, the voltage of the fourth node N4 may not be affected by the second node N2 due to the fourth transistor T4 during the third period P3. Thus, the voltage of the fourth node N4 of each of the first and second pixels PX1 and PX2 may be equal to or substantially each other (e.g., which may be determined according to Equation 2 above). Each of the first and second pixels PX1 and PX2 stores the data voltage of the first level received in the second horizontal period HP2 in the third node N3. This means that the voltage difference between the third and fourth nodes N3 and N4 of the first pixel PX1 may be the same or substantially the same as the voltage difference between third and fourth nodes N3 and N4 of the second pixel PX2. Accordingly, the first and second pixels PX1 and PX2 may emit light of the same luminance as each other, and the display panel 110 may display an image with improved reliability.

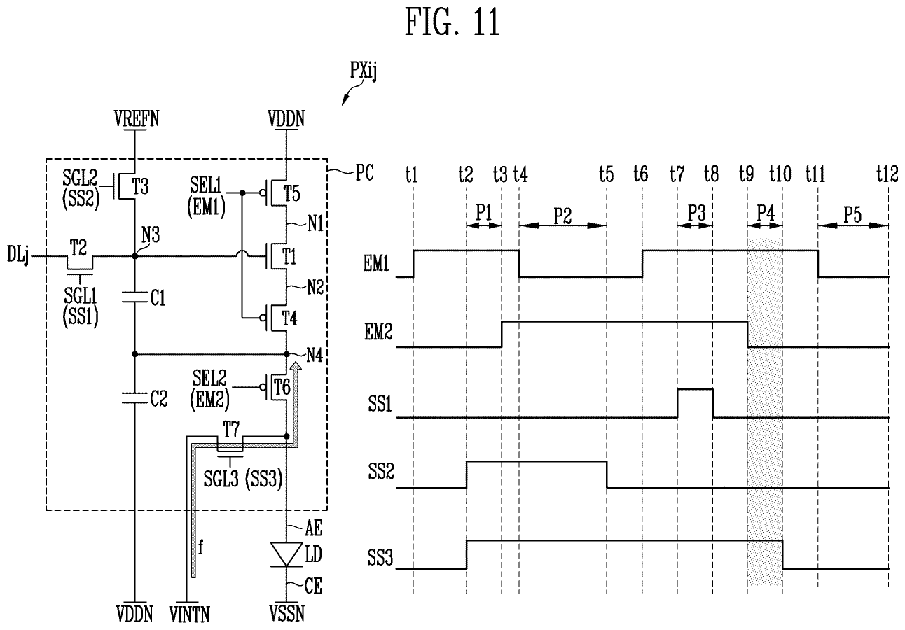

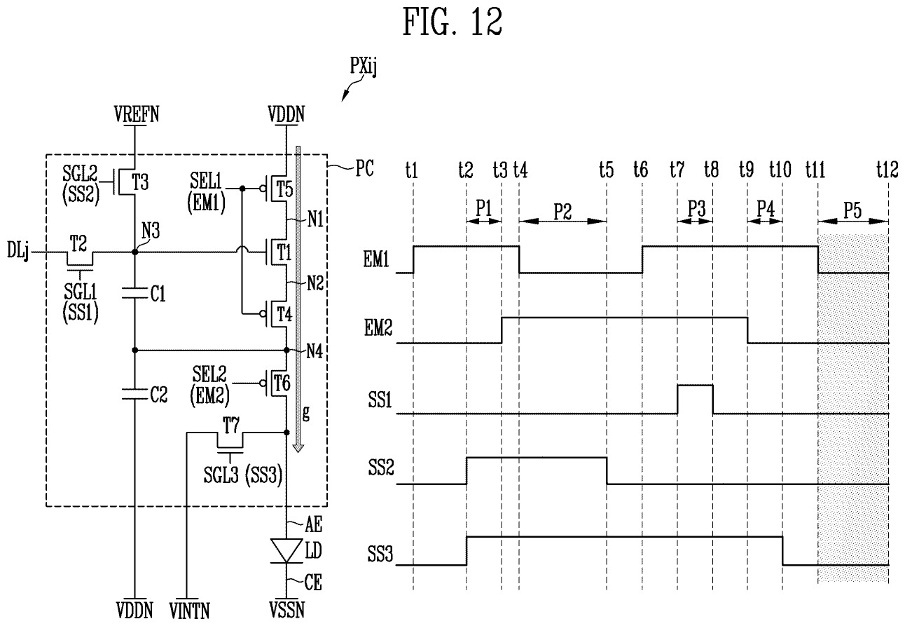

FIGS. 11 and 12 are diagrams illustrating operations of a pixel in fourth and fifth periods of FIG. 5.

Referring to FIG. 11, in a fourth period P4 between the ninth and tenth times t9 and t10, the first sub-light emitting control signal EM1 has the gate off voltage, the second sub-light emitting controls signal EM2 has the gate on voltage, the first and second sub-scan signals SS1 and SS2 have the gate off voltage, and the third sub-scan signal SS3 has the gate on voltage.

The initialization voltage VINT of the initialization voltage node VINTN may be transmitted to the fourth node N4 via the turned on sixth and seventh transistors T6 and T7 (e.g., see f). As such, in the fourth period P4, the fourth node N4 may be initialized with the initialization voltage VINT. Due to the coupling of the first capacitor C1, the voltage difference between the third and fourth nodes N3 and N4 may be maintained or substantially maintained.

In some embodiments, the operation of initializing the voltage of the fourth node N4 in the fourth period P4 may be omitted as needed or desired. In this case, the third sub-scan signal SS3 may transition to the gate off voltage before the ninth time t9.

Referring to FIG. 12, in a fifth period P5 between the eleventh and twelfth times t11 and t12, the first and second sub-light emitting control signals EM1 and EM2 have the gate on voltage, and the first to third sub-scan signals SS1 to SS3 have the gate off voltage. Accordingly, the fourth to sixth transistors T4 to T6 are turned on. Due to the coupling of the first capacitor C1, the voltage difference between the third and fourth nodes N3 and N4 may be maintained or substantially maintained.

The first transistor T1 may be turned on to adjust the current according to the voltage difference between the gate electrode and the source electrode thereof. Depending on the voltage difference between the third and fourth nodes N3 and N4, the first transistor T1 may adjust the current flowing from the first power supply voltage node VDDN through the light emitting element LD to the second power supply voltage node VSSN. The current flowing through the light emitting element LD may be determined according to a value obtained by subtracting the threshold voltage of the first transistor T1 from the voltage difference between the third and fourth nodes N3 and N4. For example, the current flowing through the light emitting element LD may be determined according to Equation 3.

$$\begin{matrix}ILD = u \times {( Vgs - Vth )}^{2} \\ = u \times ( DV - ( VREF - Vth ) - \frac{C 1}{C 1 - C 2} \times ( DV - VREF ) - Vth ) \\ = u \times \frac{C 2}{C 1 - C 2} \times ( DV - VREF ) ) :\end{matrix} \qquad Equation 3$$

In Equation 3, ILD denotes a current flowing through the light emitting element LD, u denotes a constant associated with the light emitting element LD, Vgs denotes a voltage difference between the gate electrode of the first transistor T1 and the source electrode of the first transistor T1, and Vth denotes a threshold voltage of the first transistor T1. In the fifth period P5, the fourth transistor T4 is turned on, so that the gate electrode of the first transistor T1 is connected to the third node N3 and the source electrode of the first semiconductor transistor T1 is coupled to the fourth node N4. Thus, in the fifth period P5, Vgs is the voltage difference between the third and fourth nodes N3 and N4.

As shown in Equations 1 and 2 above, the voltage of the fourth node N4 may reflect the threshold voltage of the first transistor T1. As shown in Equation 3 above, the current ILD flowing through the light emitting element LD may be determined according to a value obtained by subtracting the threshold voltage of the first transistor T1 from the voltage difference between the third and fourth nodes N3 and N4. Thus, as represented in Equation 3 above, the current ILD flowing through the light emitting element LD may be determined without being affected by the threshold voltage of the first transistor T1.

In addition, as described above, the voltage of the fourth node N4 in the third period P3 may not be affected by the second node N2 due to the fourth transistor T4. As such, the voltage of the fourth node N4 in the third period P3 may not be affected by the data voltage corresponding to the pixel in the previous pixel row. Thus, each pixel may emit light without being affected by the data voltage corresponding to a pixel in a previous pixel row.

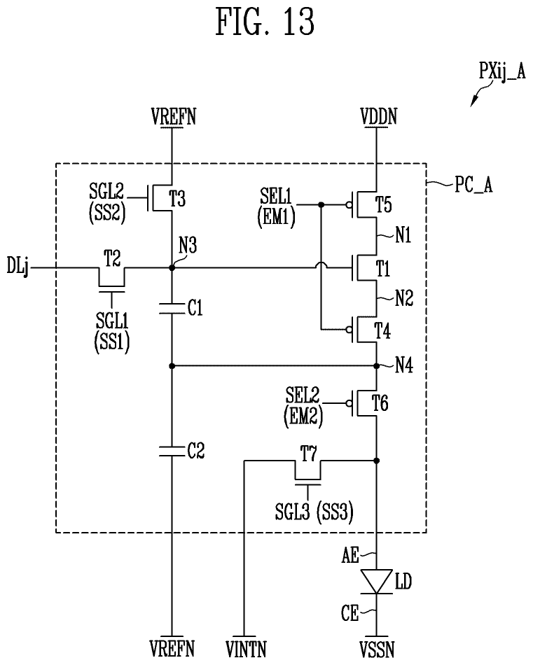

FIG. 13 is a circuit diagram of the pixel in FIG. 2 according to an embodiment.

Referring to FIG. 13, the pixel PXij_A includes a pixel circuit PC_A and a light emitting element LD.

The light emitting element LD is configured the same or substantially the same as (or similarly to) that of the light emitting element LD described above with reference to FIG. 4.

The pixel circuit PC_A includes first to seventh transistors T1 to T7, and first and second capacitors C1 and C2. The first to seventh transistors T1 to T7 and the first capacitor C1 are configured the same or substantially the same as (or similarly to) those of the first to seventh transistors T1 to T 7 and the first capacitor C1 described above with reference to FIG. 4.

One end of the second capacitor C2 is connected to the fourth node N4, and another end (e.g., an opposite end) of the second capacitance C2 is connected with the reference voltage node VREFN. In the pixel circuit PC_A, the reference voltage node VREFN may be connected to each of the third transistor T3 and the second capacitor C2. As such, the other end of the second capacitor C2 may be connected to a voltage node having one of various suitable voltage levels.

The pixel PXij_A of FIG. 13 may be driven the same or substantially the same as (or similar to) the pixel PXij of FIG. 4 as described above with reference to FIG. 5.

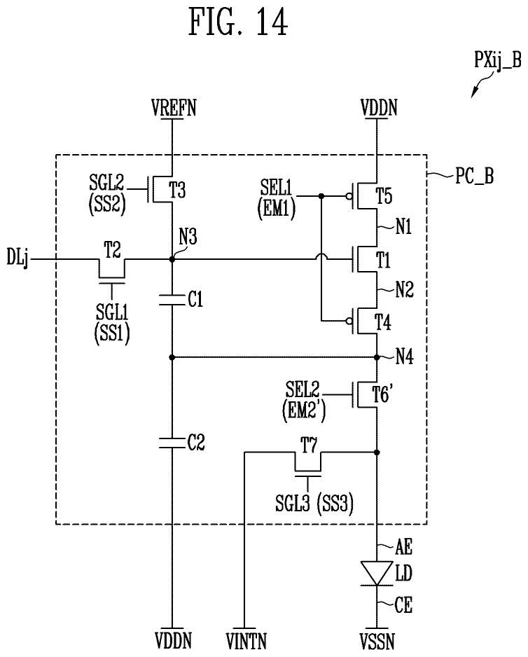

FIG. 14 is a circuit diagram of the pixel of FIG. 2 according to an embodiment.

Referring to FIG. 14, the pixel PXij_B includes a pixel circuit PC_B and a light emitting element LD.

The light emitting element LD is configured the same or substantially the same as (or similarly to) that of the light emitting element LD described above with reference to FIG. 4.

The sixth transistor T6′ is connected between the fourth node N4 and the anode electrode AE, and the gate electrode of the sixth transistor T6′ is connected to the second sub-light emitting control line SEL2. Compared to the sixth transistor T6 described above with reference to FIG. 4, the sixth transistor T6′ of FIG. 14 may be provided as an N-type transistor. For example, the sixth transistor T6′ may be an NMOS transistor or an oxide thin film transistor including an oxide semiconductor. Accordingly, the second sub-light control signal EM2′ provided via the second sub-light emitting control line SEL2 may have the gate on voltage of a logic level high.

The first to fifth transistors T1 to T5, the seventh transistor T7, and the first and second capacitors C1 and C2 may be configured the same or substantially the same as (or similarly to) those of the pixel circuit PC described above with reference to FIG. 4.

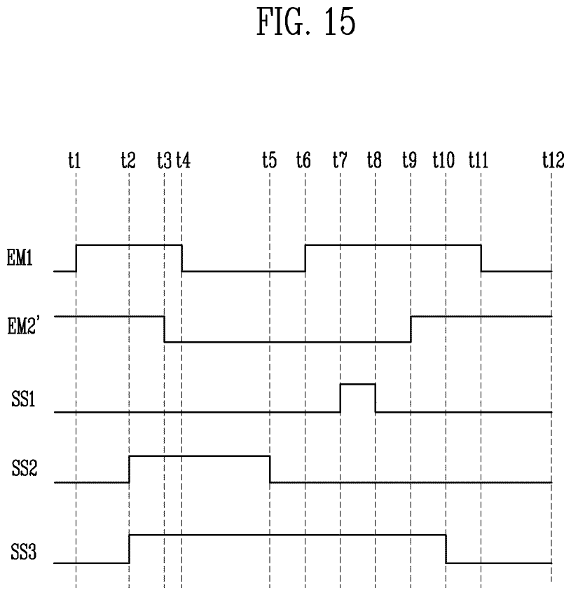

FIG. 15 is a timing diagram illustrating signals applied to the pixel of FIG. 14 according to an embodiment.

Referring to FIGS. 14 and 15, compared to the second sub-light emitting control signal EM2 described above with reference to FIG. 5, the second sub-light emitting control signal EM2′ of FIG. 15 has a logic high level as the gate on voltage and has a logic low level as the gate off voltage. For example, the second sub-light emitting control signal EM2′ may correspond to a signal obtained by inverting the second sub-emitting control signal EM2 described above with reference to FIG. 5.

In a period between the first and third times t1 and t3, the second sub-light emitting control signal EM2′ may have a logic high level of the gate on voltage. In a period between the third and ninth times t3 and t9, the second sub-light emitting control signal EM2′ may have the gate off voltage of a logic low level. In a period between the ninth and twelfth times t9 and t12, the second sub-light emitting control signal EM2′ may have a logic high level of the gate on voltage. Accordingly, the sixth transistor T6′ may be turned on in the period between the first and third times t1 and t3, may be turned off in the period between third and ninth times t3 and t9, and may be turned on in the period between the ninth and twelfth times t9 and t12.

The first sub-light emitting control signal EM1 and the first to third sub-scan signals SS1 to SS3 may be configured the same or substantially the same as (or similarly to) those of the first sub-light emitting control signal EM1 and the first to fourth sub-scan signal SS1 to SS3 described above with reference to FIG. 5, respectively.

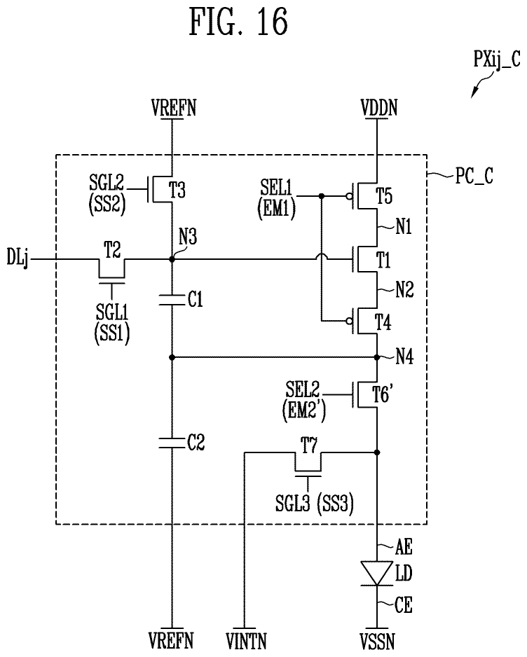

FIG. 16 is a circuit diagram of the pixel in FIG. 2 according to an embodiment.

Referring to FIG. 16, the pixel PXij_C includes a pixel circuit PC_C and a light emitting element LD.

The light emitting element LD is configured the same or substantially the same as (or similarly to) that of the light emitting element LD described above with reference to FIG. 4.

The pixel circuit PC_C includes first to fifth transistors T1 to T5, a sixth transistor T6′, a seventh transistor T7, a first capacitor C1, and a second capacitor C2.

The first to fifth transistors T1 to T5, the sixth transistor T6′, the seventh transistor T7, and the first capacitor C1 may be configured in the same or substantially the same manner as those of the first to fifth transistors T1 to T5, the sixth transistor T6′, the seventh transistor T7, and the first capacitance C1 described above with reference to FIG. 13.

One end of the second capacitor C2 is connected to the fourth node N4, and another end (e.g., an opposite end) of the second capacitance C2 is connected with the reference voltage node VREFN. In the pixel circuit PC_C, the reference voltage node VREFN may be connected to each of the third transistor T3 and the second capacitor C2.

The pixel PXij_C of FIG. 16 may be driven the same or substantially the same as (or similar to) the pixel PXij_B of FIG. 14 as described above with reference to FIG. 15.

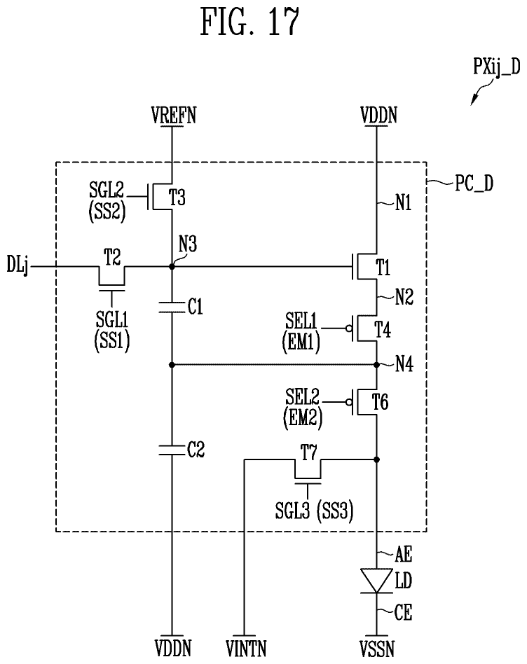

FIG. 17 is a circuit diagram of the pixel in FIG. 2 according to an embodiment.

Referring to FIG. 17, the pixel PXij_D includes a pixel circuit PC_D and a light emitting element LD.

The light emitting element LD is configured the same or substantially the same as (or similarly to) that of the light emitting element LD described above with reference to FIG. 4.

The pixel circuit PC_D includes first to fourth transistors T1 to T4, a sixth transistor T6, a seventh transistor T7, a first capacitor C1, and a second capacitor C2.

The pixel circuit PC_D of FIG. 17 may not include the fifth transistor T5 described above with reference to FIG. 4. In other words, the fifth transistor T5 described above with reference to FIG. 4 may be omitted as needed or desired. In this case, the first transistor T1 may be directly connected to the first power supply voltage node VDDN.

The second to fourth transistors T2 to T4, the sixth transistor T6, the seventh transistor T7, the first capacitor C1, and the second capacitor C2 may be configured the same or substantially the same as (or similarly to) those of the second to fourth transistors T2 to T4, the sixth transistor T6, the seventh transistor T7, the first capacitor C1, and the second capacitor C2 described above with reference to FIG. 4, respectively.

Pixel PXij_D of FIG. 17 may be driven the same or substantially the same as (or similar to) that of the pixel PXij of FIG. 4 as described above with reference to FIG. 5. For example, the first sub-light emitting control signal EM1, the second sub-light emitting controls signal EM2, the first sub-scan signal SS1, the second sub-scan signal SS2, and the third sub-scan signals SS3 may be provided in the same or substantially the same manner as those described above with reference to FIG. 5.

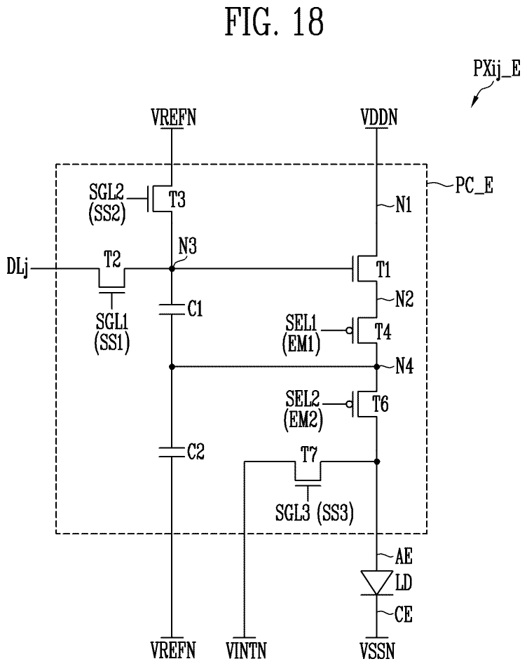

FIG. 18 is a circuit diagram of the pixel in FIG. 2 according to an embodiment.

Referring to FIG. 18, the pixel PXij_E includes a pixel circuit PC_E and a light emitting element LD.

The light emitting element LD is configured in the same or substantially the same manner as that of the light emitting device described above with reference to FIG. 17.

The pixel circuit PC_E of FIG. 18 may differ from the pixel circuit PC_D described above with reference to FIG. 17, in that the second capacitor C2 may be connected between the fourth node N4 and the reference voltage node VREFN. As such, the second capacitor C2 may be connected to one voltage node having various suitable voltage levels.

The pixel PXij_E of FIG. 18 may be driven the same or substantially the same as (or similar to) that of the pixel PXij of FIG. 4 as described above with reference to FIG. 5.

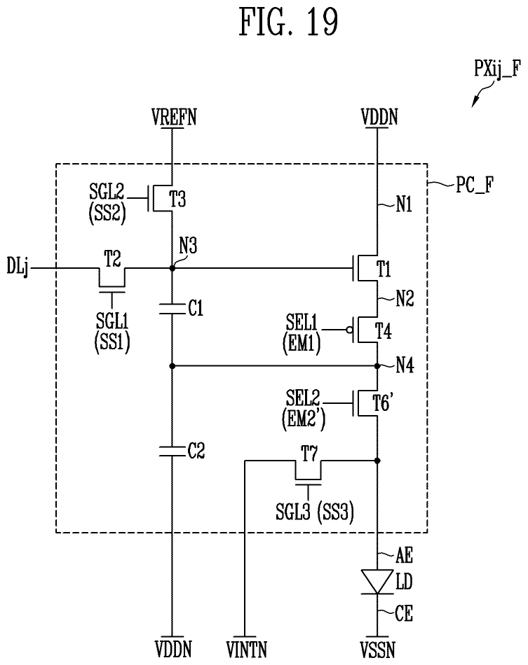

FIG. 19 is a circuit diagram of the pixel in FIG. 2 according to an embodiment.

Referring to FIG. 19, the pixel PXij_F includes a pixel circuit PC_F and a light emitting element LD.

The light emitting element LD is configured the same or substantially the same as (or similarly to) that of the light emitting element LD described above with reference to FIG. 17.

The sixth transistor T6′ is connected between the fourth node N4 and the anode electrode AE, and the gate electrode of the sixth transistor T6′ is connected to the second sub-light emitting control line SEL2. The pixel circuit PXij_F may be different from the pixel circuit PC_D described above with reference to FIG. 17, in that the sixth transistor T6′ is an N-type transistor. For example, the sixth transistor T6′ may be an NMOS transistor or an oxide thin film transistor including an oxide semiconductor. Accordingly, the second sub-light control signal EM2′ provided via the second sub-light emitting control line SEL2 may have the gate on voltage of a logic level high.

The first to fourth transistors T1 to T4, the seventh transistor T7, and the first and second capacitors C1 and C2 may be configured the same or substantially the same as (or similarly to) those of the pixel circuit PCij_D described above with reference to FIG. 17.

The pixel PXij_F of FIG. 19 may be driven the same or substantially the same as (or similar to) that of the pixel PXij_B of FIG. 14 as described above with reference to FIG. 15. For example, the first sub-light emitting control signal EM1, the second sub-light emitting controls signal EM2′, the first sub-scan signal SS1, the second sub-scan signal SS2, and the third sub-scan signal SS3 may be provided in the same or substantially the same manner as those described above with reference to FIG. 15.

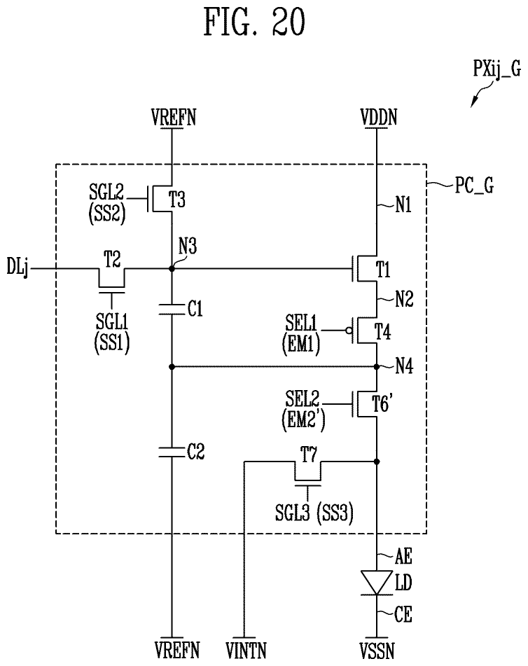

FIG. 20 is a circuit diagram of the pixel in FIG. 2 according to an embodiment.

Referring to FIG. 20, the pixel PXij_G includes a pixel circuit PC_G and a light emitting element LD.

The light emitting element LD is configured the same or substantially the same as (or similarly to) that of the light emitting element LD described above with reference to FIG. 17.

The pixel circuit PC_G in FIG. 20 may differ from the pixel circuit PC_F described above with reference to FIG. 19, in that the second capacitor C2 is connected between the fourth node N4 and the reference voltage node VREFN. As such, the second capacitor C2 may be connected to one voltage node of various suitable voltage levels.

The pixel PXij_G of FIG. 20 may be driven the same or substantially the same as (or similar to) that of the pixel PXij_B of FIG. 14 as described above with reference to FIG. 15.

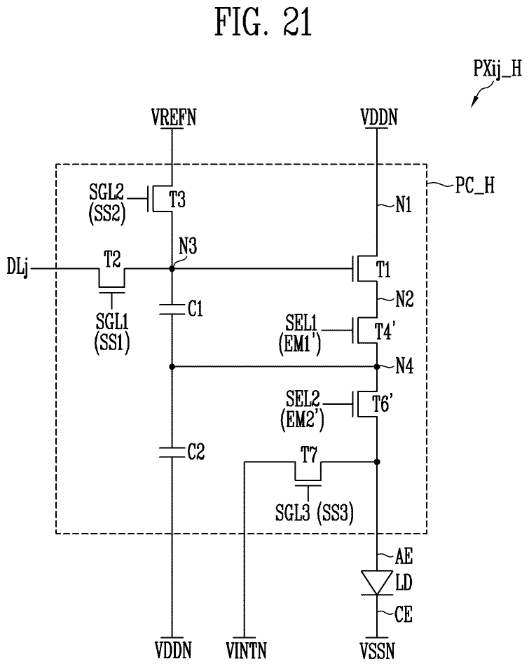

FIG. 21 is a circuit diagram of the pixel of FIG. 2 according to an embodiment.

Referring to FIG. 21, the pixel PXij_H includes a pixel circuit PC_H and a light emitting element LD.

The light emitting element LD is configured the same or substantially the same as (or similarly to) that of the light emitting element LD described above with reference to FIG. 17.

The fourth transistor T4′ is connected between the second node N2 and the fourth node N4. The gate electrode of the fourth transistor T4′ is connected to the first sub-light emitting control line SEL1. The pixel circuit PXij_H may be different from the pixel circuit PC_F described above with reference to FIG. 19, in that the fourth transistor T4′ is an N-type transistor. For example, the fourth transistor T4′ may be an NMOS transistor or an oxide thin film transistor including an oxide semiconductor. Accordingly, the first sub-light emitting control signal EM1′ provided via the first sub-light emitting control line SEL1 may have the gate on voltage of a logic level high.

The first to third transistors T1 to T3, the sixth transistor T6′, the seventh transistor T7, and the first and second capacitors C1 and C2 may be configured the same or substantially the same as (or similarly to) those of the pixel circuit PC_F described above with reference to FIG. 19.

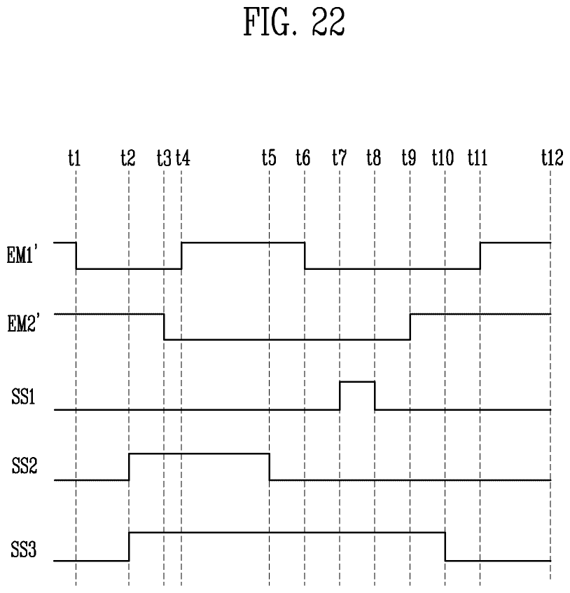

FIG. 22 is a timing diagram illustrating signals applied to the pixel of FIG. 21 according to an embodiment.

Referring to FIGS. 21 and 22, compared to the first sub-light emitting control signal EM1 described above with reference to FIG. 15, the first sub-emitting control signal EM1′ of FIG. 22 has a logic high level as the gate on voltage and a logic low level as the gate off voltage. For example, the first sub-light emitting control signal EM1′ may correspond to a signal obtained by inverting the first sub-light emitting control signal EM1 described above with reference to FIG. 15.

In a period between the first and fourth times t1 and t4, the first sub-light emitting control signal EM1′ may have the gate off voltage of the logic low level. In a period between the fourth and sixth times t4 and t6, the first sub-light emitting control signal EM1′ may have the gate on voltage of the logic high level. In a period between the sixth and eleventh times t6 and t11, the first sub-light emitting control signal EM1′ may have the gate off voltage of the logic low level. In a period between the eleventh and twelfth times t11 and t12, the first sub-light emitting control signal EM1′ may have the gate on voltage of the logic high level. Accordingly, the fourth transistor T4′ may be turned off in the period between the first and fourth times t1 and t4, may be turned on in the period between fourth and sixth times t4 and t6, may be turned off in the period between the sixth and eleventh times t6 and t11, and may be turned on in the period between eleventh and twelfth times t11 and t12.

The second sub-light emitting control signal EM2′ and the first to third sub-scan signals SS1 to SS3 may be configured the same or substantially the same as (or similarly to) those of the second sub-light emitting control signal EM2′ and the first to fourth sub-scan signal SS1 to SS3, respectively, described above with reference to FIG. 15.

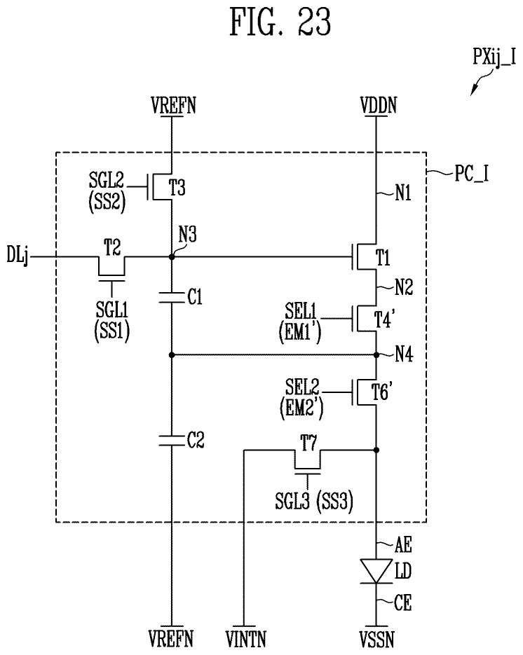

FIG. 23 is a circuit diagram of the pixel in FIG. 2 according to an embodiment.

Referring to FIG. 23, the pixel PXij_I includes a pixel circuit PC_I and a light emitting element LD.

The light emitting element LD is configured the same or substantially the same as (or similarly to) that of the light emitting element LD described above with reference to FIG. 17.

The pixel circuit PC_I may differ from the pixel circuit PC_H described above with reference to FIG. 21, in that the second capacitor C2 is connected between the fourth node N4 and the reference voltage node VREFN. As such, the second capacitor C2 may be connected to a voltage node of one of various suitable voltage levels.

The pixel PXij_I may be driven the same or substantially the same as (or similar to) that of the pixel the PXij_H of FIG. 21 as described above with reference to FIG. 22.

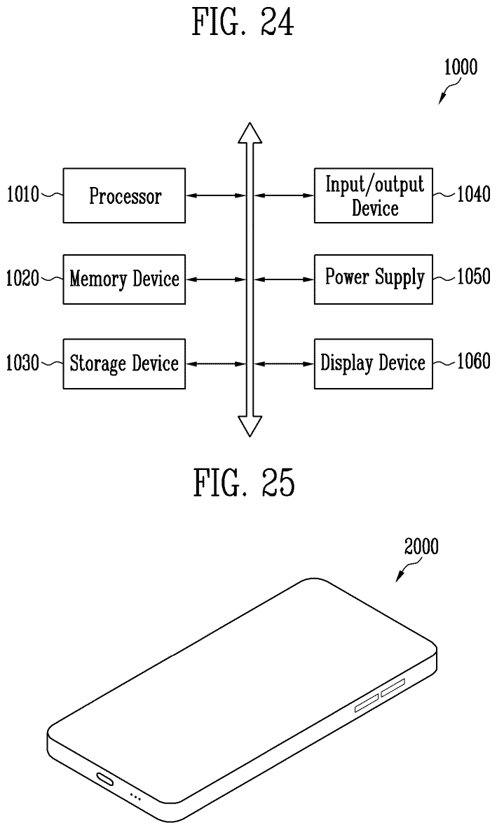

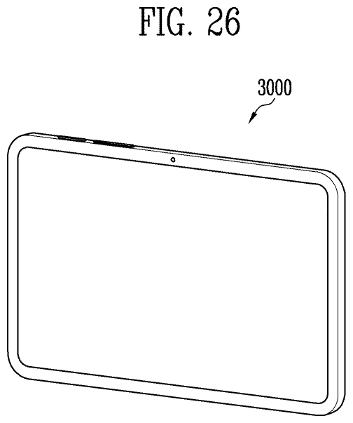

FIG. 24 is a block diagram of a display system including the display device of FIG. 1 according to an embodiment. FIG. 25 is a perspective view illustrating an example of a smartphone that may be implemented using the display system of FIG. 24. FIG. 26 is a perspective view illustrating an example of a tablet computer that may be implemented using the display system of FIG. 24.

Referring to FIG. 24, the display system 1000 may include a processor 1010, a memory device 1020, a storage device 1030, an input/output device 1040, a power supply device 1050, and a display device 1060.

In some embodiments, as shown in FIG. 25, the display system 1000 may be implemented by a smartphone 2000. In other embodiments, as shown in FIG. 26, the display system 1000 may be implemented as a tablet computer 3000. However, the present disclosure is not limited thereto, and the display system 1000 is not limited thereto. For example, the display system 1000 may be a computer device or an electronic device including a display device 1060, such as a digital television, a 3D TV, a personal computer (PC), a home electronic device, a laptop computer, a mobile phone, a video phone, a smart pad, a smart watch, a head mounted display device, a personal digital assistant (PDA), a portable multimedia player (PMP), a digital camera, a music player, a portable game console, a navigation, or the like.

The processor 1010 may perform various suitable tasks and calculations. In some embodiments, the processor 1010 may include an application processor, a graphics processing unit, a microprocessor, a central processing unit (CPU), or the like. The processor 1010 may be connected to the other components of the display system 1000 via a bus system. In some embodiments, the bus system may include a Peripheral Component Interconnect (PCI) bus. The processor 1010 may provide a data stream to be displayed on the display device 1060. The data stream may be provided to the display device 1060 as the input image data IMG described above with reference to FIG. 1. The processor 1010 may further transmit the control signal CTRL described above with reference to FIG. 1 to the display device 1060.

The memory device 1020 may be provided as a working memory and/or a buffer memory of the display system 1000 and/or the processor 1010. In some embodiments, the memory device 1020 may include volatile memory devices, such as dynamic random access memory (DRAM), static random access memory (SRAM), mobile DRAM, and the like.

The storage device 1030 may store data in response to a control of the processor 1010. The storage device 1030 may include a non-volatile storage medium that retains data even when the display system 1000 is powered off. In some embodiments, the storage device 1030 may include a Solid State Drive (SSD), a Hard Disk Drive (HDD), or the like.

The input/output device 1040 may include user input devices, such as a keyboard, a keypad, a touchpad, a touchscreen, a mouse, and the like, and output devices, such as a speaker, a printer, and the like.

The power supply device 1050 may supply power used for the operation of the display system 1000. For example, the power supply 1050 may be a power management integrated circuit (PMIC). For example, the power supply 1050 may include a battery.

The display device 1060 may display an image in response to the control of the processor 1010. The display device 1060 may be connected to the other components of the display system 1000 via a bus system and/or other suitable communication links. The display device 1060 may be implemented as the display device 100 described above with reference to FIG. 1. An image may be displayed in the pixels PX of the display device 1060, and each of the pixels PX may be configured as any one of the pixels PXij, PXij_A, PXij_B, PXij_C, PXij_D, PXij_E, PXij_F, PXij_G, PXij_H, and/or PXij_I described above with reference to FIGS. 4, 13, 14, 16 to 21, and/or 23.

According to some embodiments, pixels, a display device including the pixels, and a display system including the pixels, which may be suitable for displaying an image with improved reliability, may be provided.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A pixel of a display device, the pixel comprising:
a first transistor connected between a first node and a second node, and comprising a gate electrode connected to a third node, the first node being connected to a first power supply voltage node;
a second transistor connected between a data line and the third node, and comprising a gate electrode connected to a first sub-gate line;
a third transistor connected between a reference voltage node and the third node, and comprising a gate electrode connected to a second sub-gate line;
a first capacitor connected between the third node and a fourth node;
a fourth transistor connected between the second node and the fourth node, and comprising a gate electrode connected to a first sub-light emitting control line; and
a light emitting element connected between the fourth node and a second power supply voltage node.

2. The pixel of claim 1, wherein:
the first transistor, the second transistor, and the third transistor are N-type transistors; and
the fourth transistor is a P-type transistor.

3. The pixel of claim 2, wherein:
each of the first transistor, the second transistor, and the third transistor comprises an oxide semiconductor; and
the fourth transistor comprises a low temperature polysilicon (LTPS) transistor.

4. The pixel of claim 1, further comprising a fifth transistor connected between the fourth node and an anode electrode of the light emitting element, and comprising a gate electrode connected to a second sub-light emitting control line different from the first sub-light emitting control line.

5. The pixel of claim 4, wherein:
the first transistor, the second transistor, and the third transistor are N-type transistors; and
the fourth transistor and the fifth transistor are P-type transistors.

6. The pixel of claim 4, wherein:
the first transistor, the second transistor, the third transistor, and the fifth transistor are N-type transistors; and
the fourth transistor is a P-type transistor.

7. The pixel of claim 4, further comprising a sixth transistor connected between the anode electrode of the light emitting element and an initialization voltage node, and comprising a gate electrode connected to a third sub-gate line.

8. The pixel of claim 1, further comprising a seventh transistor connected between the first power supply voltage node and the first node, and comprising a gate electrode connected to the first sub-light emitting control line.

9. The pixel of claim 1, further comprising a second capacitor connected between the fourth node and the first power supply voltage node.

10. The pixel of claim 1, further comprising a second capacitor connected between the fourth node and the reference voltage node.

11. A display device comprising:
pixels connected to gate lines and light emitting control lines;
a gate driver configured to control the gate lines; and
an emission driver configured to control the light emitting control lines,
wherein a first pixel of the pixels comprises:
a first transistor connected between a first node and a second node, and comprising a gate electrode connected to a third node, the first node being connected to a first power supply voltage node;
a second transistor connected between a data line and the third node, and comprising a gate electrode connected to a first sub-gate line of one of the gate lines;
a third transistor connected between a reference voltage node and the third node, and comprising a gate electrode connected to a second sub-gate line of the one of the gate lines;
a first capacitor connected between the third node and a fourth node;
a fourth transistor connected to the second node, and comprising a gate electrode connected to a first sub-light emitting control line of one of the light emitting control lines; and
a light emitting element connected between the fourth node and a second power supply voltage node.

12. The display device of claim 11, wherein the first pixel further comprises:
a fifth transistor connected between the fourth node and an anode electrode of the light emitting element, and comprising a gate electrode connected to a second sub-light emitting control line of the one of the light emitting control lines; and
a sixth transistor connected between the anode electrode of the light emitting element and an initialization voltage node, and comprising a gate electrode connected to a third sub-gate line of the one of the gate lines.

13. The display device of claim 12, wherein the first pixel further comprises a seventh transistor connected between the first power supply voltage node and the first node, and comprising a gate electrode connected to the first sub-light emitting control line.

14. The display device of claim 13, wherein a first period, a second period, a third period, a fourth period, and a fifth period are sequentially provided,
wherein the emission driver is configured to:
apply a first sub-light emitting control signal of a gate on voltage to the first sub-light emitting control line in the second period and the fifth period to turn on the fourth and seventh transistors; and
apply a second sub-light emitting control signal of a gate on voltage to the second sub-light emitting control line in the first period, the fourth period, and the fifth period to turn on the fifth transistor, and
wherein the gate driver is configured to:
apply a first sub-scan signal of a gate on voltage to the first sub-gate line in the third period to turn on the second transistor;
apply a second sub-scan signal of a gate on voltage to the second sub-gate line in the first period and the second period to turn on the third transistor; and
apply a third sub-scan signal of a gate on voltage to the third sub-gate line in the first to fourth periods to turn on the sixth transistor.

15. The display device of claim 14, wherein the third period comprises two horizontal periods.

16. The display device of claim 14, further comprising a data driver connected to the pixels via data lines,
wherein the first pixel of the pixels is connected to one of the data lines, and
wherein the data driver is configured to apply, in the third period, a first data signal corresponding to the first pixel and a second data signal corresponding to a second pixel of the pixels to the one of the data lines.

17. The display device of claim 16, wherein:
the pixels comprise a plurality of pixel rows;
the first pixel of the pixels is included in a first pixel row of the plurality of pixel rows; and
the second pixel is included in a second pixel row adjacent to the first pixel row of the plurality of pixel rows.

18. A display system comprises:
a processor; and
a display device comprising pixels, and configured to display an image in the pixels under a control of the processor;
wherein a first pixel of the pixels comprises:
a first transistor connected between a first node and a second node, and comprising a gate electrode connected to a third node, the first node being connected to a first power supply voltage node;
a second transistor connected between a data line and the third node, and comprising a gate electrode connected to a first sub-gate line;
a third transistor connected between a reference voltage node and the third node, and comprising a gate electrode connected to a second sub-gate line;
a first capacitor connected between the third node and a fourth node;
a fourth transistor connected between the second node and the fourth node, and comprising a gate electrode connected to a first sub-light emitting control line; and
a light emitting element connected between the fourth node and a second power supply voltage node.

19. The display system of claim 18, wherein the first pixel further comprises a fifth transistor connected between the fourth node and an anode electrode of the light emitting element, and comprising a gate electrode connected to a second sub-light emitting control line different from the first sub-light emitting control line; and
a sixth transistor connected between the anode electrode of the light emitting element and an initialization voltage node, and comprising a gate electrode connected to a third sub-gate line.

20. The display system of claim 18, wherein the first pixel further comprises a seventh transistor connected between the first power supply voltage node and the first node, and comprising a gate electrode connected to the first sub-light emitting control line.
